(19) United States
(12) Patent Application Publication
(10) Pub. No.: US 2026/0304778 A1
(43) Pub. Date: Oct. 1, 2026

(54) FERROELECTRIC MEMORY DEVICE

(71) Applicant: Samsung Electronics Co., Ltd., Suwon-si (KR)

(72) Inventors: Jeonil Lee, Suwon-si (KR); Sam Park, Suwon-si (KR)

(73) Assignee: Samsung Electronics Co., Ltd., Suwon-si (KR)

(21) Appl. No.: 19/576,830

(22) Filed: Mar. 24, 2026

(30) Foreign Application Priority Data
Mar. 25, 2025 (KR) 10-2025-0038188

(51) Int. Cl. H10B 51/20; G11C 5/06; H10B 51/30; H10D 30/01; H10D 30/67; H10D 30/69; H10D 64/68

(52) U.S. Cl. CPC H10B 51/20; G11C 5/063; H10B 51/30; H10D 30/6728; H10D 30/6733; H10D 30/6735; H10D 30/6744; H10D 30/6755; H10D 30/6757; H10D 30/701; H10D 64/689; H10D 30/0318; H10D 30/0415

(57) ABSTRACT

In a ferroelectric memory device having a vertical channel layer, a 2D material layer, and a ferroelectric layer, the 2D material layer includes an insulating material so that the 2D material layer acts as a gate dielectric layer. The ferroelectric memory device has the 2D material layer between the vertical channel layer and the ferroelectric layer as a gate dielectric layer so as to lessen surface defects of the vertical channel layer, thereby improving durability and reliability.

### CROSS-REFERENCE TO RELATED APPLICATIONS

This present application claims priority to and the benefit under 35 U.S.C. § 119(a)-(d) of Korean Patent Application No. 10-2025-0038188, filed on Mar. 25, 2025, in the Korean Intellectual Property Office, the entire disclosure of which is incorporated herein by reference.

### FIELD

The disclosed concepts related to a ferroelectric memory device, and in particular, to a ferroelectric memory device having spontaneous polarization characteristics.

### BACKGROUND

Recently, according to the high-speed and low-power consumption tendency of electronic products, fast reading/writing operations and low operating voltage of a semiconductor device built in an electronic device are in demand. According to the necessity, research has been conducted into a ferroelectric memory device having ferroelectricity, which maintains spontaneous polarization because electric dipole moments are aligned even when an electric field is not applied thereto from outside. In particular, a ferroelectric memory device that is highly-integrated is highlighted as a next-generation memory device because the ferroelectric memory device is capable of performing fast reading and fast writing operations, and has a non-volatile property.

### SUMMARY

According to embodiments, provided is a ferroelectric memory device including a source line extending in a first horizontal direction, a plurality of vertical channel layers extending in a vertical direction on the source line, a two-dimensional (2D) material layer having a plurality of first vertical portions surrounding outer walls of the plurality of vertical channel layers and a first horizontal portion connecting upper portions of the plurality of first vertical portions to one another while extending in the first horizontal direction, a ferroelectric layer having a plurality of second vertical portions surrounding outer walls of the plurality of first vertical portions and a second horizontal portion connecting upper portions of the plurality of second vertical portions to one another while extending in the first horizontal direction, a plurality of word lines coming into contact with outer walls of the plurality of second vertical portions of the ferroelectric layer, being spaced apart from one another in the first horizontal direction, and extending in a second horizontal direction that crosses the first horizontal direction, and a bit line coming into contact with the plurality of vertical channel layers and the first horizontal portion of the 2D material layer, and extending in the first horizontal direction.

According to embodiments, there is provided a ferroelectric memory device including a source line extending in a first horizontal direction, a plurality of vertical channel layers extending in a vertical direction on the source line, a plurality of two-dimensional (2D) material layers extending in a vertical direction while surrounding outer walls of the plurality of vertical channel layers, a ferroelectric layer including a plurality of vertical portions surrounding outer walls of the plurality of 2D material layers and a horizontal portion extending in the first horizontal direction while connecting upper portions of the plurality of vertical portions, a plurality of word lines coming into contact with an outer wall of the ferroelectric layer, being spaced apart from one another in the first horizontal direction, and extending in a second horizontal direction that crosses the first horizontal direction, and a bit line extending in the first horizontal direction while coming into contact with the plurality of vertical channel layers, the plurality of 2D material layers, and the horizontal portion of the ferroelectric layer, wherein the plurality of word lines have gate-all-around (GAA) structures surrounding the plurality of vertical channel layers corresponding thereto.

According to embodiments, there is provided a ferroelectric memory device including a source line extending in a first horizontal direction, a vertical channel layer including an oxide semiconductor material and having an inner wall and an outer wall, on the source line, a two-dimensional (2D) material layer conformally arranged on the inner wall of the vertical channel layer, a ferroelectric layer conformally arranged on an inner wall of the 2D material layer, a pair of word lines that are arranged on both side walls of the ferroelectric layer and extend in a second horizontal direction crossing the first horizontal direction, and a bit line coming into contact with the vertical channel layer and extending in the first horizontal direction.

According to embodiments, there is provided a method of manufacturing a ferroelectric memory device, the method including forming a plurality of vertical channel layers on a substrate, the plurality of vertical channel layers extending in a vertical direction, forming a two-dimensional (2D) material layer so as to conformally surround an upper surface of the substrate and the plurality of vertical channel layers, forming a ferroelectric layer so as to conformally surround the 2D material layer, forming a plurality of word lines coming into contact with an outer wall of the ferroelectric layer, being spaced apart from one another in a first horizontal direction, and extending in a second horizontal direction that crosses the first horizontal direction, etching a part of the 2D material layer and a part of the ferroelectric layer so as to expose upper surfaces of the plurality of vertical channel layers, forming a source line extending in the first horizontal direction, on the plurality of vertical channel layers, the 2D material layer, and the ferroelectric layer, turning over the substrate in a vertical direction, and removing the substrate, and forming a bit line extending in the first horizontal direction, on the plurality of vertical channel layers and the 2D material layer.

In some embodiments, the forming of the plurality of vertical channel layers may include forming each of the plurality of vertical channel layers to have a cylindrical shape.

In some embodiments, each of the plurality of vertical channel layers may be formed by using single-crystalline silicon (Si).

In some embodiments, the forming of the 2D material layer may include forming the 2D material layer as an insulating material layer, and the 2D material layer may include a gate dielectric layer.

In some embodiments, the forming of the 2D material layer may include forming the 2D material layer as one type of insulating material layer.

In some embodiments, the forming of the 2D material layer may include forming a first 2D material layer so as to conformally surround an upper surface of the substrate and the plurality of vertical channel layers, and forming a second 2D material layer conformally surrounding the first 2D material layer.

In some embodiments, the forming of the ferroelectric layer may include forming the ferroelectric layer so as to conformally surround the second 2D material layer.

In some embodiments, the forming of the plurality of word lines may include forming the plurality of word lines to have gate-all-around (GAA) structures surrounding the plurality of vertical channel layers corresponding thereto.

In some embodiments, the method may further include, after the forming of the plurality of word lines, forming a back-gate electrode between the plurality of word lines.

In some embodiments, in the forming of the ferroelectric layer, the ferroelectric layer may include any one selected from hafnium oxide (HFO), doped HfO, hafnium zirconium oxide (HfZrO), and hafnium silicon oxide (HfSiO).

### BRIEF DESCRIPTION OF THE DRAWINGS

Embodiments will be more clearly understood from the following detailed description taken in conjunction with the accompanying drawings in which:

FIG. 1 is a layout of a ferroelectric memory device according to embodiments;

FIG. 2 is a cross-sectional view of the ferroelectric memory device taken along line A1-A1′ of FIG. 1;

FIG. 3 is a perspective view showing the three-dimensional locational relationship among main elements of FIG. 2;

FIGS. 4 to 13 are diagrams of a ferroelectric memory device according to embodiments;

FIG. 14 is a flowchart illustrating a method of manufacturing a ferroelectric memory device, according to embodiments;

FIGS. 15 to 21 are cross-sectional views illustrating a method of manufacturing a ferroelectric memory device according to embodiments, according to processing order; and

FIG. 22 is a block diagram of a system including a ferroelectric memory device according to embodiments.

### DETAILED DESCRIPTION

Hereinafter, one or more embodiments of the disclosed concepts will be described in detail with reference to accompanying drawings.

Embodiments of the present disclosed concepts provide a ferroelectric memory device having improved endurance and reliability.

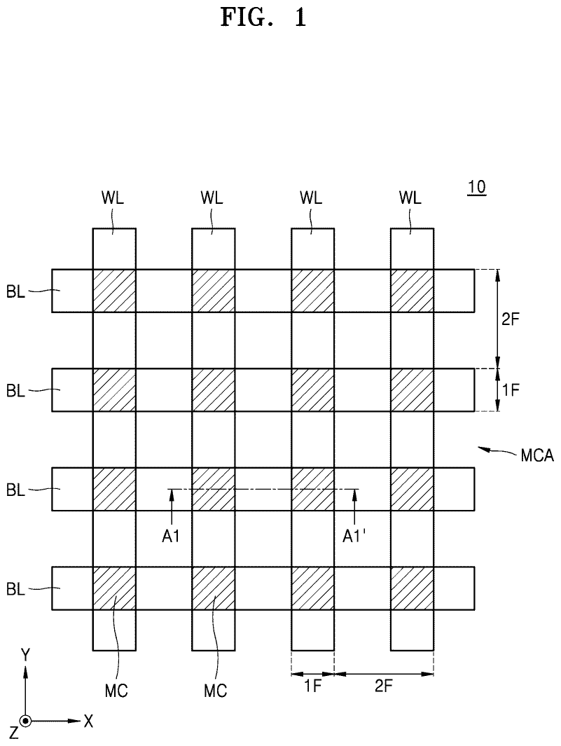

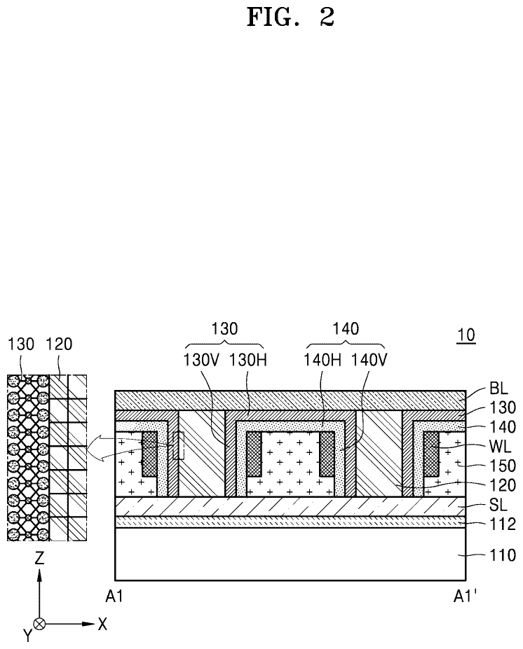

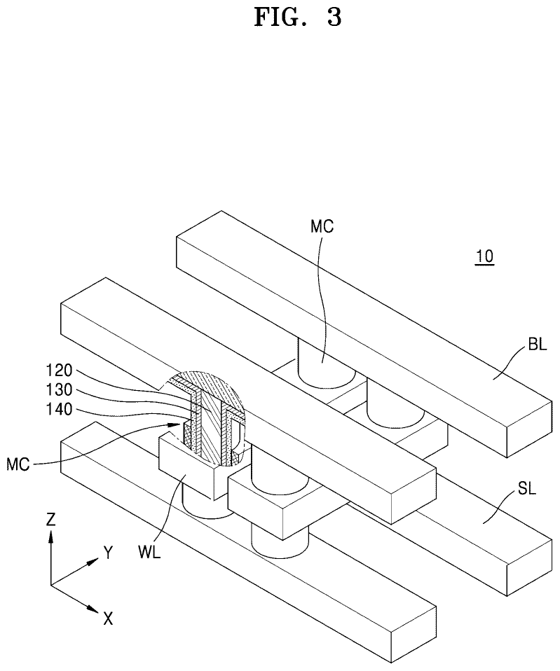

FIG. 1 is a layout of a ferroelectric memory device according to embodiments. FIG. 2 is a cross-sectional view of the ferroelectric memory device taken along line A1-A1′ of FIG. 1. FIG. 3 is a perspective view showing the three-dimensional locational relationship among main elements of FIG. 2.

Referring to FIGS. 1 to 3, a ferroelectric memory device 10 may have a memory cell array area MCA including a vertical channel transistor (VCT).

In some embodiment, the memory cell array area MCA may have a shape in which memory cells MC are arranged in an array. Although not shown in the drawings, a peripheral circuit area may include a peripheral circuit transistor (not shown) for transferring a signal and/or power to the memory cells MC included in the memory cell array area MCA. The peripheral circuit transistor may configure various circuits such as a command decoder, a control logic, an address buffer, a row decoder, a column decoder, a sense amplifier, a data input/output circuit, etc.

In the memory cell array area MCA of the substrate 110, a plurality of bit lines BL extending in a first horizontal direction X and a plurality of word lines WL extending in a second horizontal direction Y crossing the first horizontal direction X may be arranged. The plurality of memory cells MC may be arranged on cross-points between the plurality of bit lines BL and the plurality of word lines WL.

In some embodiments, the plurality of bit lines BL may each have a width of 1F and a pitch (that is, the sum of width and interval) of the plurality of bit lines BL may be 2F. Also, a width of the plurality of word lines WL may be 1F, and a pitch of the plurality of word lines WL may be 2F. Accordingly, a unit area for forming one memory cell MC may be 4F2. That is, because the plurality of memory cells MC may be of a cross-point type requiring a relatively small unit area, the integration of the ferroelectric memory device 10 may be improved.

A lower insulating layer 112 may be arranged on a substrate 110. In some embodiments, the substrate 110 may include silicon (Si), e.g., single-crystalline silicon, polycrystalline silicon, or amorphous silicon. In some embodiments, the substrate 110 may include at least one selected from Ge, SiGe, SiC, GaAs, InAs, and InP. Also, the lower insulating layer 112 may include, for example, silicon oxide, silicon nitride, or a combination thereof.

Source lines SL extending in the first horizontal direction X may be arranged on the lower insulating layer 112. In some embodiments, the source line SL may include Ti, TiN, Ta, TaN, W, WN, TiSiN, WSiN, polysilicon, or a combination thereof. A source line insulating layer (not shown) extending in the first horizontal direction X may be arranged on the side wall of the source line SL. For example, the source line insulating layer may be formed to the same height as that of the source line SL while filling a space between two neighboring source lines SL.

A plurality of vertical channel layers 120 extending in the vertical direction Z may be arranged on the source lines SL. The plurality of vertical channel layers 120 may be arranged to be spaced apart from one another in the first horizontal direction X on the source lines SL. Also, the plurality of vertical channel layers 120 may be spaced apart from one another at certain intervals in the second horizontal direction Y. That is, the plurality of vertical channel layers 120 may be arranged in the first horizontal direction X and the second horizontal direction Y crossing one another.

The plurality of vertical channel layers 120 may include a single-crystalline semiconductor material. In some embodiments, the plurality of vertical channel layers 120 may include Si, in particular, single-crystalline Si. In some embodiments, the plurality of vertical channel layers 120 may be formed of doped Si having a certain doping concentration with a certain conductive type, by adjusting a dopant and/or doping concentration during the formation process. In some embodiments, the plurality of vertical channel layers 120 may each have a cylindrical shape. However, the disclosed concepts are not limited thereto, and each of the plurality of vertical channel layers 120 may have a square column shape or a hexagonal column shape.

A two-dimensional (2D) material layer 130 includes a plurality of first vertical portions 130V surrounding the outer walls of the plurality of vertical channel layers 120 and a first horizontal portion 130H connecting the upper portions of the plurality of first vertical portions 130V to one another and extending in the first horizontal direction X. The 2D material layer 130 may be arranged continuously from the plurality of vertical channel layers 120 adjacent thereto. In some embodiments, the plurality of first vertical portions 130V of the 2D material layer 130 may be arranged so as to completely surround the outer walls of the plurality of corresponding vertical channel layers 120.

In general, the 2D material layer 130 has stabilized and excellent characteristics, even with a small thickness of 1 nm or less, and thus, is highlighted as a material capable of overcoming the limitation, that is, the performance degradation caused due to the reduction in the size of a semiconductor device. The 2D material layer 130 may have a monolayer or a multilayer structure, and each layer may have a thickness at an atomic level. The 2D material layer 130 may include, for example, first to tenth layers, but is not limited thereto.

In embodiments, the 2D material 130 includes an insulating material, and thus, the 2D material layer 130 may act as a gate dielectric layer. For example, the 2D material layer 130 may include a hexagonal boron nitride (hBN). The hBN may have a large energy band gap of about 5 eV, and thus, is used as an insulating material for blocking the current flow.

A ferroelectric layer 140 may include a plurality of second vertical portions 140V surrounding the outer walls of the plurality of first vertical portions 130V of the 2D material layer 130 and a second horizontal portion 140H connecting the upper portions of the plurality of second vertical portions 140V and extending in the first horizontal direction X. The ferroelectric layer 140 may be arranged continuously from the plurality of adjacent vertical channel layers 120. In some embodiments, an upper surface of the second horizontal portion 140H of the ferroelectric layer 140 may be arranged inside the 2D material layer 130 so as to be in contact with a lower surface of the first horizontal portion 130H of the 2D material layer 130.

In general, the ferroelectric layer 140 may have ferroelectricity for maintaining spontaneous polarization due to the alignment of the electric dipole moments therein, even when an electric field is not applied thereto from the outside.

In embodiments, the ferroelectric layer 140 may include a high-k material having a higher dielectric constant than that of the silicon oxide. For example, the ferroelectric layer 140 may include any one selected from hafnium oxide (HfO), doped HfO, hafnium zirconium oxide (HfZrO), and hafnium silicon oxide (HfSiO). A dopant of the doped HfO may include any one selected from Zr, La, Y, Gd, Si, Al, and a combination thereof. In some embodiments, the ferroelectric layer 140 may have a single thin film structure, a stacked thin film structure, or a composite layer structure having a laminate structure.

The plurality of word lines WL may be arranged between the source lines SL and bit lines BL. Also, the plurality of word lines WL come into contact with the outer walls of the plurality of second vertical portions 140V of the ferroelectric layer 140, and are spaced apart from one another in the first horizontal direction X while extending in the second horizontal direction Y. A vertical length of the word line WL may be less than that of the vertical channel layer 120. The word line WL may include, for example, doped polysilicon, metal, conductive metal nitride, conductive metal silicide, conductive metal oxide, or a combination thereof.

In embodiments, the plurality of word lines WL may have gate-all-around (GAA) structures surrounding the plurality of corresponding vertical channel layers 120 from all directions. That is, the vertical channel layer 120, the first vertical portion 130V of the 2D material layer 130, and the second vertical portion 140V of the ferroelectric layer 140 constituting one memory cell MC may be surrounded by the word line WL from all directions.

A first insulating pattern 150 may be arranged between two neighboring word lines WL. The first insulating pattern 150 may include, for example, silicon oxide layer, silicon oxynitride layer, or silicon nitride layer. The first insulating pattern 150 may be referred to as a word line insulating pattern.

The bit line BL may be arranged on the upper surfaces of the plurality of vertical channel layers 120 and the first horizontal portions 130H of the 2D material layer 130 while extending in the first horizontal direction X. In some embodiments, the bit line BL may include Ti, TiN, Ta, TaN, W, WN, TiSiN, WSiN, polysilicon, or a combination thereof. A bit line insulating layer (not shown) may be arranged on a side wall of the bit line BL, the bit line insulating layer extending in the first horizontal direction X. For example, the bit line insulating layer may be formed to the same height as that of the bit line BL while filling the space between two neighboring bit lines BL.

A lower surface of the bit line BL may come into contact with the upper surfaces of the plurality of vertical channel layers 120, and may be arranged to come into contact with the upper surfaces of the first horizontal portions 130H of the 2D material layer 130. As described below, this may be a characteristic caused by a method of manufacturing the ferroelectric memory device 10 according to the disclosed concepts.

The integration degree of a memory device is an important factor in determining economic feasibility of a product. The integration degree of a 2D memory device is mainly determined by an area occupied by unit memory cells, and thus, is largely affected by the level of fine pattern forming technology. However, expensive equipment is required to form fine patterns, and an area of a chip die is restricted. Thus, there is a limitation to increasing the integration degree of the 2D memory device. Therefore, demand for a three-dimensional (3D) memory device including a VCT has been increasing.

Also, according to the high-speed and low-power consumption tendency of electronic products, fast reading/writing operations and low operating voltage of the memory devices built in an electronic product are in demand. In particular, a ferroelectric memory device that is highly-integrated is highlighted as a next-generation memory device because the ferroelectric memory device is capable of performing fast reading and fast writing operations, and has a non-volatile property.

Accordingly, the ferroelectric memory device 10 of embodiments adopts the VCT structure, and at the same time, is configured to form a polarization having different polarities in the plurality of second vertical portions 140V of the ferroelectric layer 140 in a non-volatile way, according to the polarity of the voltage applied to the memory cells MC. According to the polarity of the polarization, the density of carriers conducting through the plurality of vertical channel layers 120 varies, and thus, electrical information may be stored in the ferroelectric memory device 10 in a non-volatile way.

However, in general, the ferroelectric memory device 10 may have an issue of weak endurance. Although it is not bound by a specific theory, it may be analyzed that the weak endurance is caused because, when the silicon oxide layer is formed on the surface of the single-crystalline Si forming the vertical channel layers 120 as a gate dielectric layer, a plurality of dangling bonds are formed on an interface between the single-crystalline Si and the silicon oxide layer, which results in degradation of interfacial characteristics.

To address the above issues, the ferroelectric memory device 10 of the disclosed concepts forms the gate dielectric layer by using the 2D material layer 130, not the silicon oxide layer, so that surface defects such as dangling bonds may be restricted from forming on the interface between the vertical channel layer 120 and the 2D material layer 130, and thus, the endurance may be effectively improved.

Ultimately, the ferroelectric memory device 10 according to the disclosed concepts may include the 2D material layer 130 arranged between the vertical channel layer 120 and the ferroelectric layer 140 as the gate dielectric layer, so as to reduce the surface defects on the vertical channel layer 120 and improve the durability and reliability thereof.

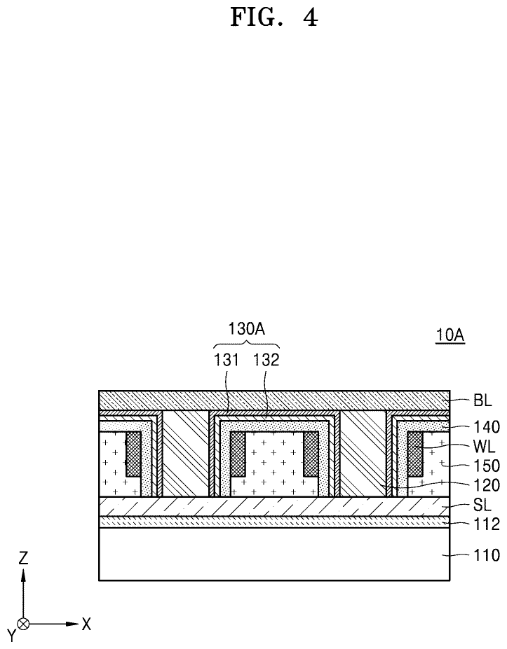

FIGS. 4 to 13 are diagrams of a ferroelectric memory device according to embodiments.

Most of the elements included in ferroelectric memory devices 10A, 10B, 20, 20A, 30, 40, 40A, 40B, 50, and 60 that are described below and materials included in the elements are substantially the same as or similar to those described above with reference to FIGS. 1 to 3. Therefore, for convenience of description, the differences from the ferroelectric memory device 10 described above are described below.

Referring to FIG. 4, the ferroelectric memory device 10A according to embodiments may have a 2D material layer 130A including multiple types of material layers.

In embodiments, the 2D material layer 130A may have a bonding structure between a first 2D material layer 131 and a second 2D material layer 132 that are different from one another. Here, the first 2D material layer 131 may come into contact with the vertical channel layer 120, and the second 2D material layer 132 may come into contact with the ferroelectric layer 140.

The first 2D material layer 131 may include a material having a relatively excellent bonding property with respect to the material forming the vertical channel layer 120, and the second 2D material layer 132 may include a material having a relative excellent bonding property with respect to the material forming the ferroelectric layer 140. Accordingly, the interfacial characteristics between the first 2D material layer 131 and the plurality of vertical channel layers 120, and the interfacial characteristics between the second 2D material layer 132 and the ferroelectric layer 140 may be excellent.

In embodiments, the first 2D material layer 131 and the second 2D material layer 132 included in the 2D material layer 130A may respectively include insulating materials, and thus, the 2D material layer 130A may act as the gate dielectric layer.

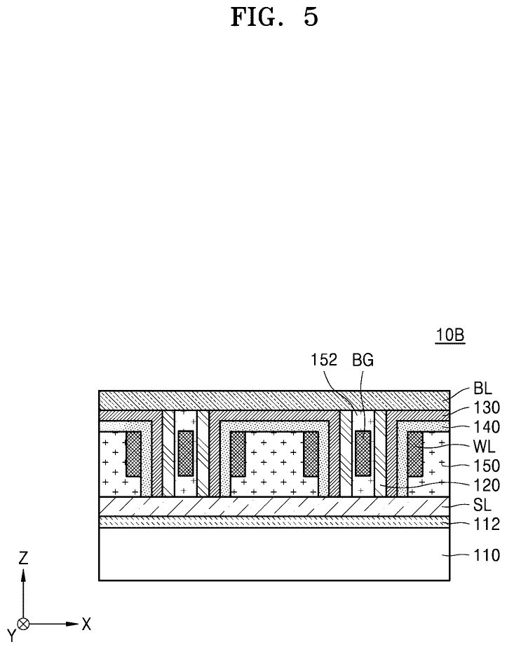

Referring to FIG. 5, the ferroelectric memory device 10B according to embodiments may include back-gate electrodes BG.

In embodiments, the back-gate electrodes BG may be spaced apart from one another at certain intervals in the first horizontal direction X between the source lines SL and the bit lines BL, and may extend in the second horizontal direction Y. Each of the back-gate electrodes BG may be arranged between two neighboring vertical channel layers 120. Here, the word lines WL may each have a line shape arranged on one side wall of the vertical channel layer 120, and may not be formed to have a GAA structure.

A negative voltage may be applied to the back-gate electrode BG during the operation of the ferroelectric memory device 10B, and thus, the threshold voltage of a transistor may increase. That is, the back-gate electrode BG may prevent degradation in a leakage current characteristic due to the decrease in the threshold voltage according to the miniaturization of the transistor.

The back-gate electrode BG may include, for example, doped polysilicon, conductive metal nitride, metal, conductive metal silicide, conductive metal oxide, or a combination thereof.

The second insulating pattern 152 may be arranged to surround the back-gate electrode BG between the two neighboring vertical channel layers 120. The second insulating pattern 152 may include, for example, silicon oxide layer, silicon oxynitride layer, or silicon nitride layer. The second insulating pattern 152 may be referred to as a back-gate insulating pattern.

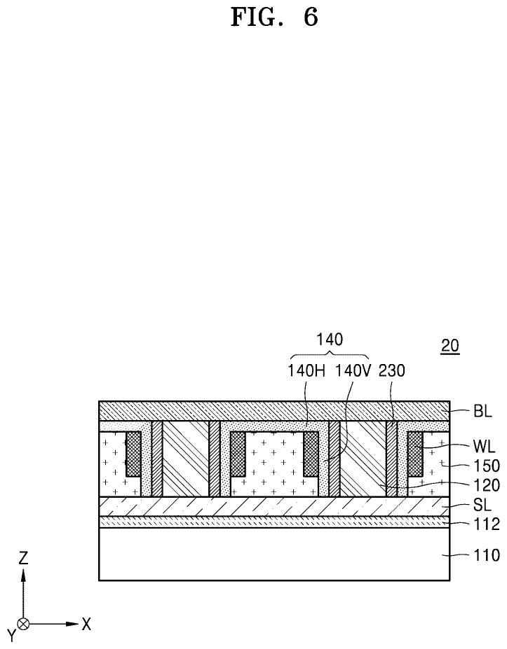

Referring to FIG. 6, the ferroelectric memory device 20 of embodiments may include a plurality of 2D material layers 230 that extend in the vertical direction Z while surrounding the outer walls of the plurality of vertical channel layers 120.

In embodiments, the plurality of 2D material layers 230 may be spaced apart from one another while completely surrounding the outer walls of the plurality of corresponding vertical channel layers 120. That is, the plurality of 2D material layers 230 may not be connected to one another. In some embodiments, the plurality of 2D material layers 230 may each have a cylindrical shape having an insulating material.

In embodiments, the ferroelectric layer 140 having a plurality of second vertical portions 140V surrounding the outer walls of the plurality of 2D material layers 230 and a second horizontal portion 140H connecting the upper portions of the plurality of second vertical portions 140V to one another and extending in the first horizontal direction X may be arranged. The ferroelectric layer 140 may be successively arranged between the plurality of neighboring vertical channel layers 120. In some embodiments, the upper surface of the second horizontal portion 140H of the ferroelectric layer 140 may be arranged to be in contact with the lower surface of the bit line BL.

Referring to FIG. 7, the ferroelectric memory device 20A according to embodiments may have a 2D material layer 230A including multiple types of material layers.

In embodiments, the ferroelectric memory device 20A may have similar structural characteristics as those of the ferroelectric memory device 20 described above. Therefore, for convenience of description, the differences from the ferroelectric memory device 20 are described below.

In embodiments, the 2D material layer 230A may have a bonding structure between a first 2D material layer 231 and a second 2D material layer 232 that are different from one another. Here, the first 2D material layer 231 may come into contact with the plurality of vertical channel layers 120, and the second 2D material layer 232 may come into contact with the ferroelectric layer 140.

Here, the first 2D material layer 231 may include a material having a relatively excellent bonding property with respect to the material forming the plurality of vertical channel layers 120, and the second 2D material layer 232 may include a material having a relatively excellent bonding property with respect to the material forming the ferroelectric layer 140. Accordingly, the interfacial characteristics between the first 2D material layer 231 and the plurality of vertical channel layers 120, and the interfacial characteristics between the second 2D material layer 232 and the ferroelectric layer 140 may be excellent.

In embodiments, the first 2D material layer 231 and the second 2D material layer 232 included in the 2D material layer 230A may respectively include insulating materials, and thus, the 2D material layer 230A may act as the gate dielectric layer.

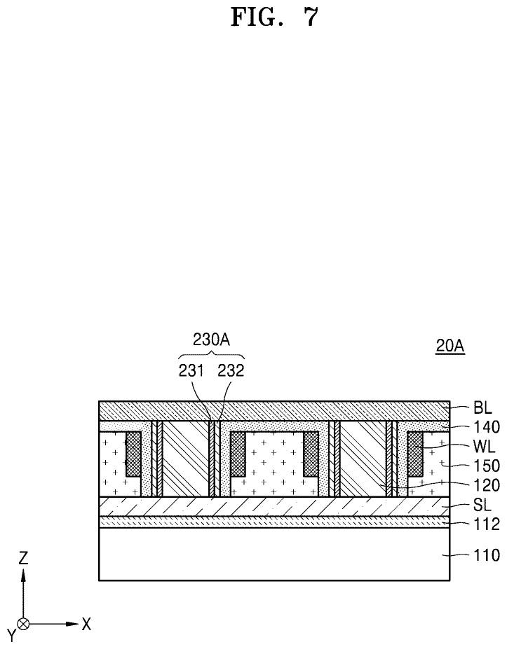

Referring to FIG. 8, the ferroelectric memory device 30 according to embodiments may include a multi-lithic type including a stack structure of memory cells MC each having a VCT structure.

In embodiments, the ferroelectric memory device 30 may include a lower memory structure 30L and an upper memory structure 30U above the lower memory structure 30L.

The lower memory structure 30L may include a plurality of memory cells MC that are arranged on the substrate 110 in the first horizontal direction X and the second horizontal direction Y in parallel with one another. In some embodiments, an interlayer insulating layer 160 may be arranged between the lower memory structure 30L and the upper memory structure 30U. The upper memory structure 30L may include a plurality of memory cells MC that are arranged on the interlayer insulating layer 160 in the first horizontal direction X and the second horizontal direction Y in parallel with one another.

In embodiments, the plurality of memory cells MC included in the lower memory structure 30L and the plurality of memory cells MC included in the upper memory structure 30U may be substantially the same as one another.

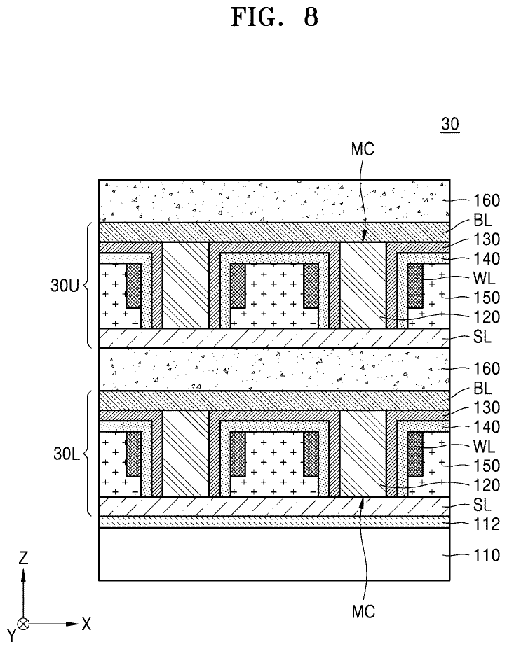

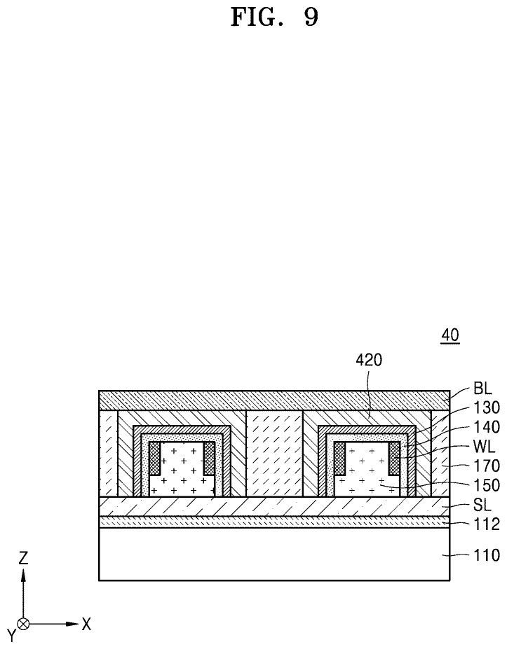

Referring to FIG. 9, the ferroelectric memory device 40 according to embodiments may include a vertical channel layer 420 including an oxide semiconductor material.

In embodiments, the ferroelectric memory device 40 may include the source line SL extending in the first horizontal direction X, the vertical channel layers 420 including an oxide semiconductor material on the source line SL and having an inner wall and an outer wall, a 2D material layer 130 conformally arranged on the inner wall of the vertical channel layer 420, the ferroelectric layer 140 conformally arranged on the inner wall of the 2D material layer 130, a pair of word lines WL arranged on both side walls of the ferroelectric layer 140 and extending in the second horizontal direction Y, and the bit line BL coming into contact with the vertical channel layers 120 and extending in the first horizontal direction X.

In embodiments, the oxide semiconductor material included in the vertical channel layer 420 may include indium (In), for example, at least one of InGaZnOx (IGZO), Sn-doped IGZO, and W-doped IGZO.

In embodiments, the 2D material 130 includes an insulating material, and accordingly, the 2D material layer 130 may act as a gate dielectric layer.

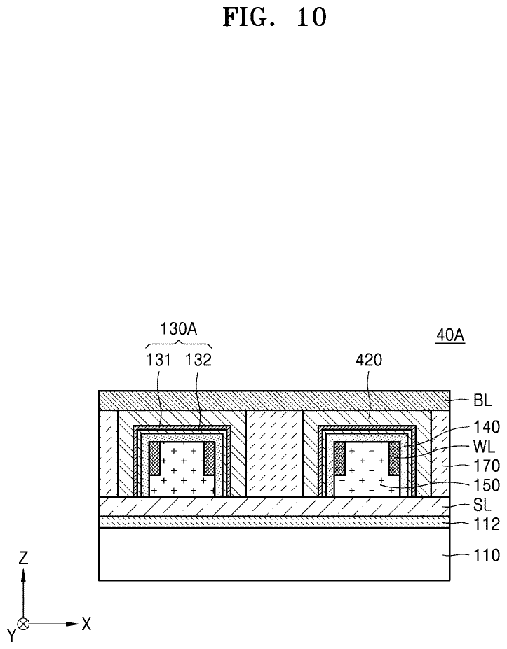

Referring to FIG. 10, the ferroelectric memory device 40A according to embodiments may have a 2D material layer 130A including multiple types of material layers.

In embodiments, the ferroelectric memory device 40A may have similar structural characteristics as those of the ferroelectric memory device 40 described above. Therefore, for convenience of description, the differences from the ferroelectric memory device 40 are described below.

In embodiments, the 2D material layer 130A may have a bonding structure between a first 2D material layer 131 and a second 2D material layer 132 that are different from one another. Here, the first 2D material layer 131 may come into contact with the channel layers 420 including the oxide semiconductor material, and the second 2D material layer 132 may come into contact with the ferroelectric layer 140.

Here, the first 2D material layer 131 may include a material having a relatively excellent bonding property with respect to the oxide semiconductor material forming the vertical channel layers 420, and the second 2D material layer 132 may include a material having a relative excellent bonding property with respect to the material forming the ferroelectric layer 140. Accordingly, the interfacial characteristics between the first 2D material layer 131 and the vertical channel layers 420, and the interfacial characteristics between the second 2D material layer 132 and the ferroelectric layer 140 may be excellent.

In embodiments, the first 2D material layer 131 and the second 2D material layer 132 included in the 2D material layer 130A may respectively include insulating materials, and thus, the 2D material layer 130A may act as the gate dielectric layer.

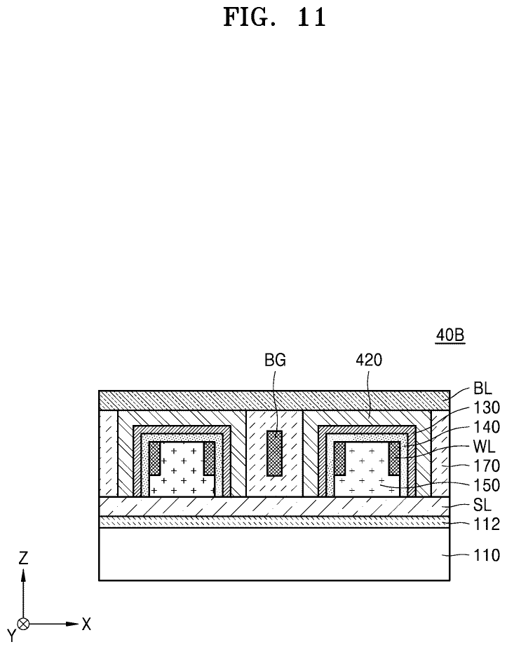

Referring to FIG. 11, the ferroelectric memory device 40B according to embodiments may include back-gate electrodes BG.

In embodiments, the ferroelectric memory device 40B may have similar structural characteristics as those of the ferroelectric memory device 40 described above. Therefore, for convenience of description, the differences from the ferroelectric memory device 40 are described below.

In embodiments, the back-gate electrodes BG may be spaced apart from one another at certain intervals in the first horizontal direction X between the source lines SL and the bit lines BL, and may extend in the second horizontal direction Y. The back-gate electrodes BG may be arranged between two neighboring vertical channel layers 420. Here, the back-gate electrode BG may be referred to as a shield electrode.

The back-gate electrode BG may include, for example, doped polysilicon, conductive metal nitride, metal, conductive metal silicide, conductive metal oxide, or a combination thereof.

The second insulating pattern 170 may be arranged to surround the back-gate electrode BG between the two neighboring vertical channel layers 420. The second insulating pattern 152 may include, for example, silicon oxide layer, silicon oxynitride layer, or silicon nitride layer.

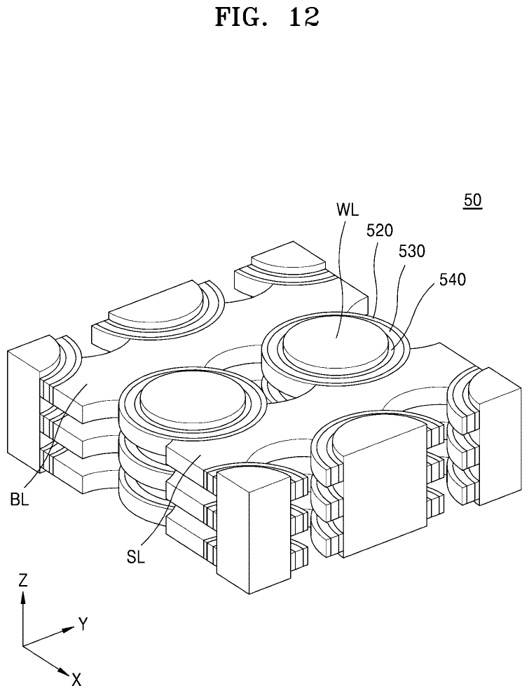

Referring to FIG. 12, the ferroelectric memory device 50 according to embodiments may be a vertical memory device including a plurality of bit lines BL that are spaced apart from one another in the vertical direction Z and stacked on one side thereof, and a plurality of source lines SL that are spaced apart from one another in the vertical direction Z and stacked on the other side thereof.

In embodiments, the ferroelectric memory device 50 may include a plurality of bit lines BL that are spaced apart from one another in the vertical direction Z and stacked, a plurality of source lines SL that are spaced apart from one another in the vertical direction Z and stacked, the word line WL formed between the bit line BL and the source line SL facing one another in the first horizontal direction X and formed lengthily in the vertical direction Z to have a cylindrical shape, a ferroelectric layer 540 having a cylindrical shape surrounding the outer wall of the word line WL, a 2D material layer 530 having a cylindrical shape surrounding the outer wall of the ferroelectric layer 540, and a vertical channel layer 520 having a cylindrical shape surrounding the outer wall of the 2D material layer 530.

In embodiments, the 2D material layer 530 includes an insulating material, and accordingly, the 2D material layer 530 may act as a gate dielectric layer.

Referring to FIG. 13, the ferroelectric memory device 60 of embodiments may be a stack memory device including a plurality of word lines WL that are stacked and spaced apart from one another in the vertical direction Z.

In embodiments, the ferroelectric memory device 60 may include a plurality of word lines WL and a plurality of insulating layers 650 that are alternately arranged in the vertical direction Z, the bit line BL penetrating through the plurality of word lines WL and the plurality of insulating layers 650 in the vertical direction Z, a channel layer 620 conformally surrounding the outer wall of the bit line BL, a 2D material layer 630 conformally surrounding the outer wall of the channel layer 620, and a ferroelectric layer 640 conformally surrounding the outer wall of the 2D material layer 630.

In embodiments, at least one end portion of the plurality of word lines WL may have a staircase shape. That is, horizontal lengths of the plurality of word lines WL in the second horizontal direction Y may increase in the downward direction in the vertical direction Z.

In embodiments, the 2D material layer 630 includes an insulating material, and accordingly, the 2D material layer 630 may act as a gate dielectric layer.

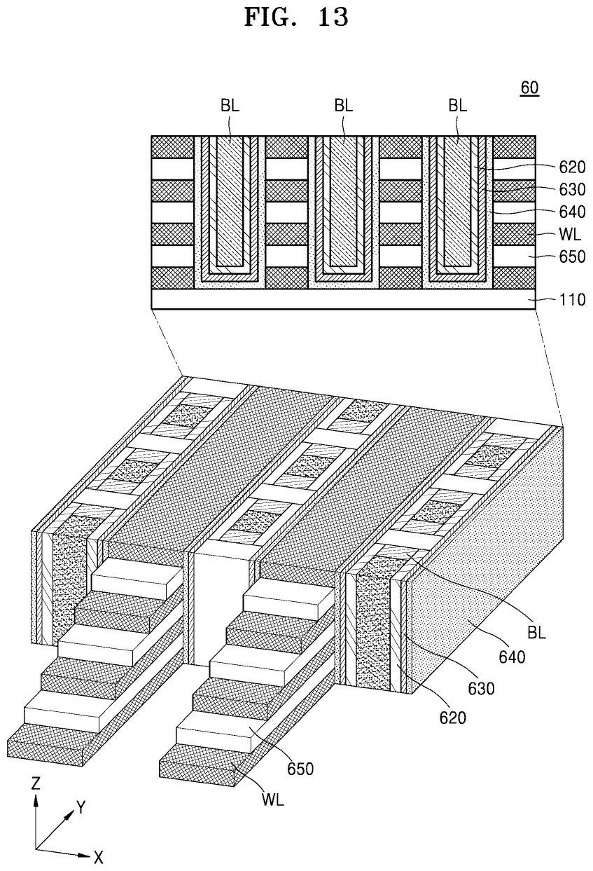

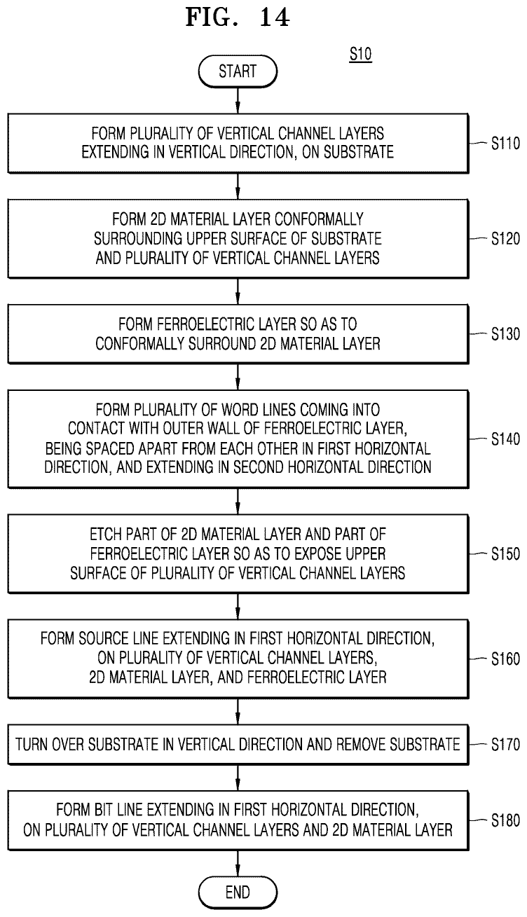

FIG. 14 is a flowchart illustrating a method of manufacturing a ferroelectric memory device, according to embodiments.

Referring to FIG. 14, the method of manufacturing a ferroelectric memory device (S10) may have a processing order of first to eighth processes (S110 to S180).

When a certain embodiment is implemented differently, a specific process order may be performed differently from the described order. For example, two consecutively described processes may be performed substantially at the same time or performed in an order opposite to the described order.

The method of manufacturing a ferroelectric memory device (S10), according to embodiments, may include first process (S110) of forming a plurality of vertical channel layers extending in the vertical direction on the substrate, second process (S120) of forming a 2D material layer so as to conformally surround the upper surface of the substrate and the plurality of vertical channel layers, third process (S130) of forming a ferroelectric layer so as to conformally surround the 2D material layer, fourth process (S140) of forming a plurality of word lines coming into contact with the outer wall of the ferroelectric layer, being spaced apart from one another in the first horizontal direction, and extending in the second horizontal direction, fifth process (S150) of partially etching the 2D material layer and the ferroelectric layer so as to expose the upper surfaces of the plurality of vertical channel layers, sixth process (S160) of forming source lines extending in the first horizontal direction, on the plurality of vertical channel layers, the 2D material layer, and the ferroelectric layer, seventh process (S170) of turning over the substrate in the vertical direction and removing the substrate, and eighth process (S180) of forming bit lines extending in the first horizontal direction on the plurality of vertical channel layers and the 2D material layer.

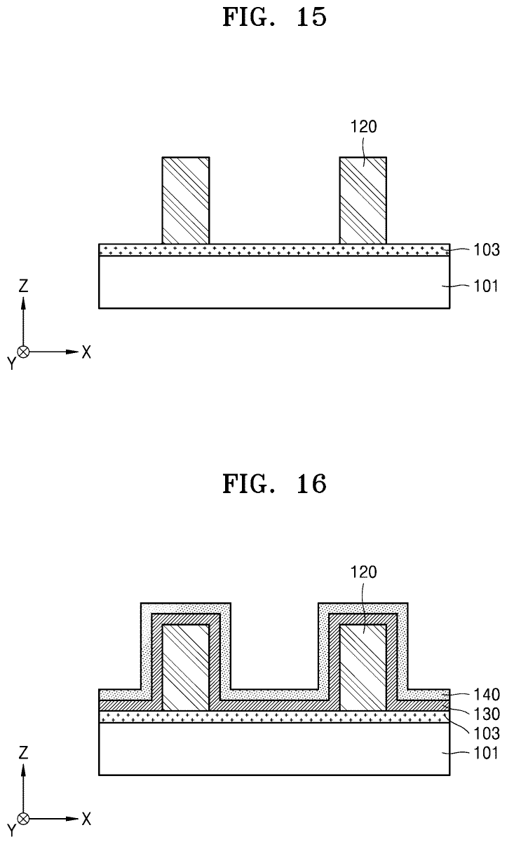

Technical features of each of the first to eighth processes (S110 to S180) are described below with reference to FIGS. 15 to 21.

FIGS. 15 to 21 are cross-sectional views illustrating a method of manufacturing a ferroelectric memory device according to embodiments, according to processing order.

Referring to FIG. 15, a first substrate 101 including a buried insulating layer 103 may be prepared.

The first substrate 101 may be a silicon-on-insulator (SOI) substrate. Alternatively, the first substrate 101 may include, for example, a silicon substrate, a germanium substrate, a silicon-germanium substrate, etc.

The buried insulating layer 103 may be provided on the first substrate 101. In some embodiments, the buried insulating layer 103 may include a buried oxide layer. In embodiments, the buried insulating layer 103 may be an insulating layer formed by a chemical vapor deposition method. The buried insulating layer 103 may include, for example, silicon oxide, silicon nitride, silicon oxynitride, and/or low-k material.

Next, a vertical channel forming layer (not shown) is formed on the buried insulating layer 103, and after that, photolithography and etching processes are performed on the vertical channel forming layer to form a plurality of vertical channel layers 120 extending in the vertical direction. For example, the plurality of vertical channel layers 120 may each include single-crystalline Si. In some embodiments, the plurality of vertical channel layers 120 may each have a cylindrical shape.

Referring to FIG. 16, the 2D material layer 130 may be formed so as to conformally surround the upper surface of the buried insulating layer 103 and upper and side surfaces of the plurality of vertical channel layers 120, on the resultant of FIG. 15.

The 2D material layer 130 may have a single-layered or multi-layered structure, and each layer may have a thickness at an atomic level. The 2D material layer 130 may include, for example, first to tenth layers, but is not limited thereto. The 2D material layer 130 may include an insulating material.

Next, the ferroelectric layer 140 may be formed to conformally surround the 2D material layer 130. The ferroelectric layer 140 may have, for example, a single thin film structure, a stacked thin film structure, or a composite layer structure having a laminate structure.

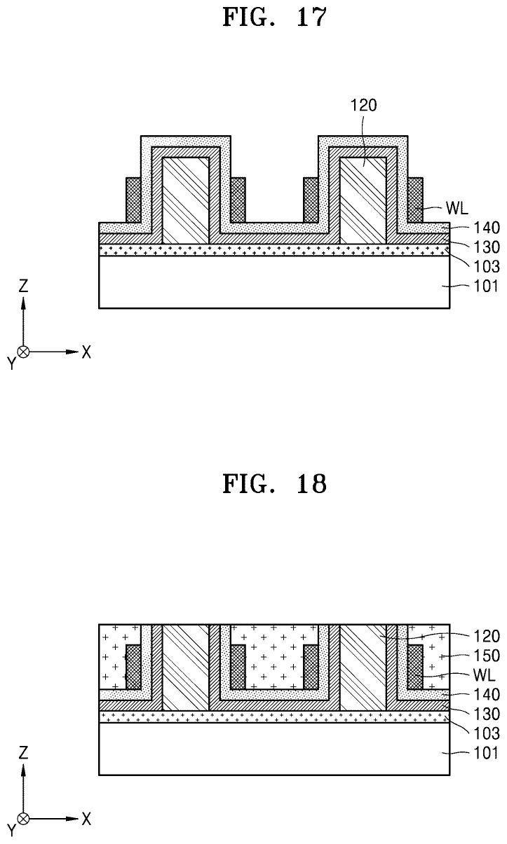

Referring to FIG. 17, the plurality of word lines WL may be formed to respectively correspond to the plurality of vertical channel layers 120 on the resultant of FIG. 16.

The plurality of word lines WL may be spaced apart from one another in the first horizontal direction X while coming into contact with the outer wall of the ferroelectric layer 140, and may extend along the second horizontal direction Y. A vertical length of the word line WL may be less than that of the vertical channel layer 120.

The plurality of word lines WL may be formed to have GAA structures surrounding the plurality of corresponding vertical channel layers 120 from all directions.

Referring to FIG. 18, the first insulating pattern 150 may be formed to surround the word lines WL on the resultant of FIG. 17.

The first insulating pattern 150 may include, for example, silicon oxide layer, silicon oxynitride layer, or silicon nitride layer.

Next, the upper portion of the ferroelectric layer 140, the upper portion of the 2D material layer 130, and the upper portion of the first insulating pattern 150 may be etched so as to expose the upper surfaces of the plurality of vertical channel layers 120. The etching process may be performed as an etch-back process or a chemical-mechanical polishing process.

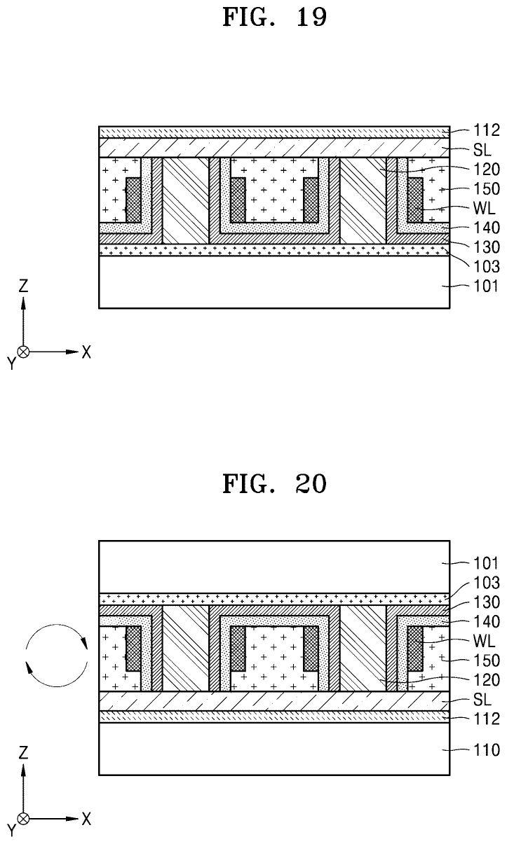

Referring to FIG. 19, the source lines SL may be formed on the polished upper surface of the resultant of FIG. 18.

A source line insulating layer (not shown) extending in the first horizontal direction (X) may be formed on the side wall of the source line SL. For example, the source line insulating layer may be formed to the same height as that of the source line SL while filling a space between two neighboring source lines SL.

Next, the lower insulating layer 112 may be formed on the source lines SL and the source line insulating layer. The lower insulating layer 112 denotes the location in a final structure, and may be interpreted as an upper insulating layer herein.

Referring to FIG. 20, the resultant of FIG. 19 is turned over in the vertical direction Z, and then may be bonded to the substrate 110.

The substrate 110 may be bonded to the lower insulating layer 112 by using a bonding interfacial layer (not shown). The substrate 110 may include silicon, e.g., single-crystalline silicon, polycrystalline silicon, or amorphous silicon. The bonding interfacial layer may include, for example, silicon carbonitride. The substrate 110 may be referred to as a second substrate so as to be discriminated from the first substrate 101.

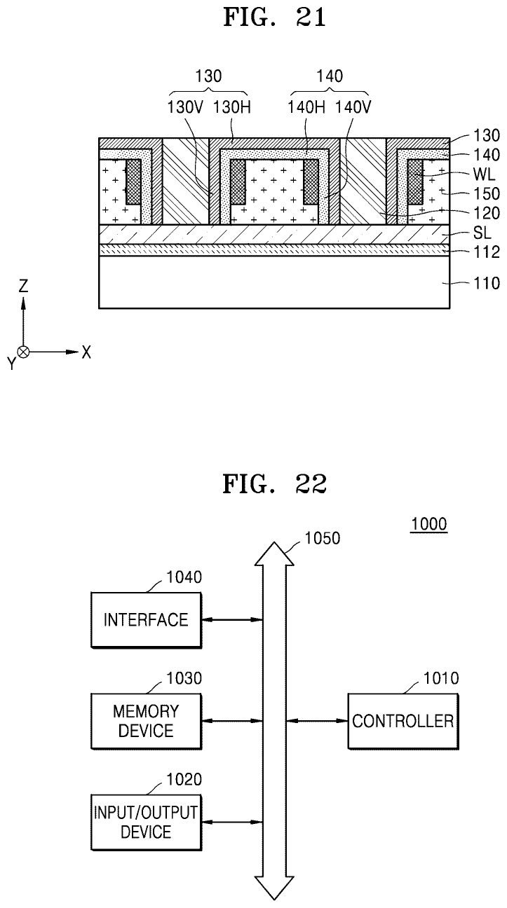

Referring to FIG. 21, on the resultant of FIG. 20, a process of removing the first substrate 101 (see FIG. 20) and the buried insulating layer 103 (see FIG. 20) may be performed.

The process of removing the first substrate 101 (see FIG. 20) and the buried insulating layer 103 (see FIG. 20) may include a process of exposing the plurality of vertical channel layers 120 and the 2D material layer 130 by sequentially performing a grinding process and a wet-etching process.

Referring back to FIG. 2, the bit line BL extending in the first horizontal direction X may be formed on the exposed plurality of vertical channel layers 120 and the exposed 2D material layer 130.

Through the above manufacturing processes, the ferroelectric memory device 10 according to embodiments may be manufactured.

FIG. 22 is a block diagram of a system including a ferroelectric memory device according to embodiments.

Referring to FIG. 22, a system 1000 may include a controller 1010, an input/output device 1020, a memory device 1030, an interface 1040, and a bus 1050.

The system 1000 may include a mobile system or a system for transmitting or receiving information. In some embodiments, the mobile system may include a portable computer, a web tablet, a mobile phone, a digital music player, or a memory card.

The controller 1010 is to control an execution program in the system 1000, and may include a micro-processor, a digital signal processor, a micro-controller, or a similar device.

The input/output device 1020 may be used to input or output data to/from the system 1000. The system 1000 may be connected to an external device, e.g., a personal computer or a network, via the input/output device, and may exchange data with the external device. The input/output device 1020 may be, for example, a touch screen, a touch pad, a keyboard, or a display.

The memory device 1030 may store data for operating the controller 1010 or data processed by the controller 1010. The memory device 1030 may include any one of the ferroelectric memory devices 10, 10A, 10B, 20, 20A, 30, 40, 40A, 40B, 50, and 60 according to embodimentss as described above.

The interface 1040 may be a data transmission passage between the system 1000 and the external device. The controller 1010, the input/output device 1020, the memory device 1030, and the interface 1040 may communicate with one another via the bus 1050.

While the disclosed concepts have been particularly shown and described with reference to embodiments thereof, it will be understood that various changes in form and details may be made therein without departing from the spirit and scope of the following claims.

What is claimed is:

1. A ferroelectric memory device comprising:
a source line extending in a first horizontal direction;
a plurality of vertical channel layers extending in a vertical direction on the source line;
a two-dimensional (2D) material layer having a plurality of first vertical portions surrounding outer walls of the plurality of vertical channel layers and a first horizontal portion connecting upper portions of the plurality of first vertical portions to one another while extending in the first horizontal direction;
a ferroelectric layer having a plurality of second vertical portions surrounding outer walls of the plurality of first vertical portions and a second horizontal portion connecting upper portions of the plurality of second vertical portions to one another while extending in the first horizontal direction;
a plurality of word lines coming into contact with outer walls of the plurality of second vertical portions of the ferroelectric layer, being spaced apart from one another in the first horizontal direction, and extending in a second horizontal direction that crosses the first horizontal direction; and
a bit line coming into contact with the plurality of vertical channel layers and the first horizontal portion of the 2D material layer, and extending in the first horizontal direction.

2. The ferroelectric memory device of claim 1, wherein:
the 2D material layer includes an insulating material layer, and
the 2D material layer includes a gate dielectric layer.

3. The ferroelectric memory device of claim 1, wherein the plurality of first vertical portions of the 2D material layer completely surround the outer walls of the plurality of vertical channel layers corresponding thereto.

4. The ferroelectric memory device of claim 3, wherein:
an upper surface of the first horizontal portion of the 2D material layer comes into contact with the bit line, and
a lower surface of the first horizontal portion of the 2D material layer comes into contact with the second horizontal portion of the ferroelectric layer.

5. The ferroelectric memory device of claim 1, wherein the 2D material layer includes one type of insulating material layer.

6. The ferroelectric memory device of claim 1, wherein:
the 2D material layer comprises multiple types of insulating material layers, and
the multiple types of insulating material layers include
a bonding structure of a first 2D material layer coming into contact with the vertical channel layers and a second 2D material layer coming into contact with the ferroelectric layer.

7. The ferroelectric memory device of claim 1, wherein each of the plurality of vertical channel layers includes single crystalline silicon (Si) having a cylindrical shape.

8. The ferroelectric memory device of claim 7, wherein the plurality of word lines have gate-all-around (GAA) structures surrounding the plurality of vertical channel layers corresponding thereto.

9. The ferroelectric memory device of claim 8, wherein a back-gate electrode is arranged between the plurality of word lines.

10. The ferroelectric memory device of claim 1, wherein:
the ferroelectric layer includes any one selected from hafnium oxide (HFO), doped HfO, hafnium zirconium oxide (HfZrO), and hafnium silicon oxide (HfSiO), and
the plurality of second vertical portions of the ferroelectric layer exhibit polarization characteristics.

11. A ferroelectric memory device comprising:
a source line extending in a first horizontal direction;
a plurality of vertical channel layers extending in a vertical direction on the source line;
a plurality of two-dimensional (2D) material layers extending in a vertical direction while surrounding outer walls of the plurality of vertical channel layers;
a ferroelectric layer including a plurality of vertical portions surrounding outer walls of the plurality of 2D material layers and a horizontal portion extending in the first horizontal direction while connecting upper portions of the plurality of vertical portions;
a plurality of word lines coming into contact with an outer wall of the ferroelectric layer, being spaced apart from one another in the first horizontal direction, and extending in a second horizontal direction that crosses the first horizontal direction; and
a bit line extending in the first horizontal direction while coming into contact with the plurality of vertical channel layers, the plurality of 2D material layers, and the horizontal portion of the ferroelectric layer,
wherein the plurality of word lines have gate-all-around (GAA) structures surrounding the plurality of vertical channel layers corresponding thereto.

12. The ferroelectric memory device of claim 11, wherein the bit line comes into contact with upper surfaces of the plurality of 2D material layers and an uppermost surface of the ferroelectric layer.

13. The ferroelectric memory device of claim 12, wherein:
each of the plurality of vertical channel layers includes single crystalline silicon (Si) having a cylindrical shape, and
each of the plurality of 2D material layers includes an insulating material having a cylindrical shape.

14. The ferroelectric memory device of claim 11, wherein:
the plurality of 2D material layers each include multiple types of insulating material layers, and
the multiple types of insulating material layers include a bonding structure of a first 2D material layer coming into contact with the vertical channel layers and a second 2D material layer coming into contact with the ferroelectric layer.

15. The ferroelectric memory device of claim 14, wherein:
an upper surface of each of the plurality of 2D material layers and an upper surface of the ferroelectric layer are at a substantially same vertical level, and
the bit line comes into contact with the upper surface of the first 2D material layer and the upper surface of the second 2D material layer.

16. A ferroelectric memory device comprising:
a source line extending in a first horizontal direction;
a vertical channel layer including an oxide semiconductor material and having an inner wall and an outer wall, on the source line;
a two-dimensional (2D) material layer conformally arranged on the inner wall of the vertical channel layer;
a ferroelectric layer conformally arranged on an inner wall of the 2D material layer;
a pair of word lines that are arranged on both side walls of the ferroelectric layer and extend in a second horizontal direction crossing the first horizontal direction; and
a bit line coming into contact with the vertical channel layer and extending in the first horizontal direction.

17. The ferroelectric memory device of claim 16, wherein:
the oxide semiconductor includes at least one of InGaZnOx (IGZO), Sn-doped IGZO, W-doped IGZO, and InZnOx, and
the ferroelectric layer includes any one selected from hafnium oxide (HFO), doped HfO, hafnium zirconium oxide (HfZrO), and hafnium silicon oxide (HfSiO).

18. The ferroelectric memory device of claim 17, wherein:
the 2D material layer is a gate dielectric layer that includes an insulating material layer, and
the insulating material layer includes hexagonal boron nitride.

19. The ferroelectric memory device of claim 17, wherein:
the 2D material layer is a gate dielectric layer that includes an insulating material layer,
the insulating material layer includes multiple types of material layers, and
the multiple types of material layers include a bonding structure of a first 2D material layer coming into contact with the vertical channel layers and a second 2D material layer coming into contact with the ferroelectric layer.

20. The ferroelectric memory device of claim 16, wherein a back-gate electrode is arranged between the vertical channel layers that are adjacent to one another.
